(19) United States
(12) Patent Application Publication
(10) Pub. No.: US 2009/0174413 A1
(43) Pub. Date: Jul. 9, 2009

(54) Method and Apparatus to Verify the Proper Connection of Loads before Applying Full DC Power

(75) Inventors: Thomas John Bucella, Rochester, NY (US); Thomas P. Dombroski, Fairport, NY (US); David E. Fuchs, Pittsford, NY (US); Jeremy M. Block, Walworth, NY (US)

Correspondence Address: BROWN & MICHAELS, PC;400 M & T BANK BUILDING, 118 NORTH TIOGA ST, ITHACA, NY, 14850, US

(73) Assignee: Teknic, Inc., Pittsford, NY (US)

(21) Appl. No.: 12/346,054

(22) Filed: Dec. 30, 2008

Related U.S. Application Data
(60) Provisional application No. 61/018,723, filed on Jan. 3, 2008.

(51) Int. Cl. G01R 31/14

(52) U.S. Cl. 324/511

(57) ABSTRACT

A DC power source or DC switching device that uses a test signal to verify the proper connection of the load (or loads) at its output prior to applying full power to the output. This method and apparatus inserts a low power or low energy test signal at the output terminals of a DC power source and measures the test signal's effect on connected external loads to access the condition and proper connection of these loads before applying full power to the DC output power port. If the test signal detects that a load is connected with a reverse polarity, is shorted, malfunctioning or can otherwise cause damage, it will inhibit the application of full power to the output terminals until the situation is corrected.

### REFERENCE TO RELATED APPLICATIONS

This application claims one or more inventions which were disclosed in Provisional Application No. 61/018,723, filed Jan. 3, 2008, entitled “Method and Apparatus to Verify the Proper Connection of Loads before Applying Full DC Power”. The benefit under 35 USC §119(e) of the U.S. provisional application is hereby claimed, and the aforementioned application is hereby incorporated herein by reference.

### BACKGROUND OF THE INVENTION

1. Field of the Invention

The invention pertains to the field of DC power supplies. More particularly, the invention pertains to load protection circuits for DC power supplies.

2. Description of Related Art

In electrical systems DC power is applied to a load (or loads) by a switching device or a power converter at the invocation of a manual or programmatic request or simply by applying power to the input of the switching device or a power converter. Typically, once power is applied and/or switched on, circuit protection devices then protect the switching device or power converter, wiring and loads if there is an error within the load(s) or wiring to the load(s).

In many of these systems, particularity when large amounts of power are to be connected to the load, the circuit protection devices will not trip fast enough to protect certain types of load errors or load wiring errors and this is especially true of loads that utilize solid state devices. In particular, circuit protection devices intended to protect the DC source and loads when loads are properly wired and properly operating will fail to protect them when they are wired improperly or have a certain class of internal errors.

There is a need for DC output power switches and power converters to protect loads and wiring in these error situations. This would be especially useful when electrical systems are being commissioned for the first time where the technician wiring the system may have introduced unintended wiring errors. Such a protection scheme should allow the system to detect the fault before enough energy is applied to the system to damage loads, wiring and/or devices so the system can then be properly re-wired. Such a system would also prevent further collateral damage to loads that are operating improperly.

There are no examples of DC power sources known to the inventor that test the load and load connections prior to applying full power when requested to supply power or when input power is supplied to them.

### SUMMARY OF THE INVENTION

The invention is a DC power source or DC switching device that uses a test signal to verify the proper connection of the load (or loads) at its output prior to applying full power to the output. This method and apparatus uses a test signal circuit to insert a low power or low energy test signal at the output terminals of a DC power source and measures the test signal's effect on connected external loads to access the condition and proper connection of these loads before applying full power to the DC output power port. If the test signal detects that a load is connected with a reverse polarity, is shorted, malfunctioning or can otherwise cause damage, it will inhibit the application of full power to the output terminals until the situation is corrected.

### BRIEF DESCRIPTION OF THE DRAWING

FIG. 1 illustrates an AC-DC rectifier, which includes a specific embodiment of this invention which uses a protective impedance to produce the test signal.

FIG. 2 illustrates an isolated AC-DC Converter which includes a specific embodiment of this invention.

FIG. 3 shows a flowchart of an example of the method of the invention.

FIG. 4 illustrates an AC-DC rectifier, which includes a specific embodiment of this invention, which uses a high-speed switch to produce the test signal.

FIG. 5 shows a DC-DC embodiment of the invention.

### DETAILED DESCRIPTION OF THE INVENTION

The invention is a DC power source or DC switching device that uses a test signal to verify the proper connection of the load (or loads) at its output prior to applying full power to the output. This method and apparatus inserts a low power or low energy test signal at the output terminals of a DC power source and measures the test signal's effect on connected external loads to access the condition and proper connection of these loads before applying full power to the DC output power port. If the test signal detects that a load is connected with a reverse polarity, is shorted, malfunctioning or can otherwise cause damage, it will inhibit the application of full power to the output terminals until the situation is corrected.

The low power or low energy test signal used in this apparatus is sufficiently limited in its power or energy such that it will not damage the intended loads or load wiring when these errant conditions occur. Additionally, this invention may stop the test signal if the errant load condition is not corrected within a certain period of time and wait for an external signal to request the initiation the test sequence again. This method and apparatus may be used on any device that supplies DC power, including but not limited to: DC output power converters, rectifiers, power switches, electronic circuit breakers, batteries, etc.

The test signal is produced by using at least one of the following methods:
(a) Connecting the intended output to the load through a protective impedance while observing the voltage and/or current at the output terminals.
(b) Regulating the output power stage to limit its current and/or voltage to a level suitable to be a test signal
(c) A method that connects the intended output power source to the load for one or more short periods of time (typically microseconds) to access the load that is connected.

The type of test signal used is dependent upon the intended load characteristics.

One important embodiment of this invention applies DC voltage to a load with a storage capacitor in parallel with a solid state load. Power is applied from the DC source through a protective impedance. If the load is connected properly, the storage capacitor will charge over time beyond a voltage threshold level at which time full power is applied by the invention. If the load is connected in the incorrect reverse polarity, the solid state circuit in the load will clamp the DC voltage to a low level (typically through parasitic components) and detecting this, full-power will not be applied by the invention.

### Embodiment 1: AC-DC Rectifier with Voltage Monitor

FIG. 1 illustrates an AC-DC rectifier, which includes a specific embodiment of this invention. In this figure, reference (11) represents a “proper” load, and references (12),(13) and (14) represent “improper” loads, as will be described in more detail below.

In this embodiment AC power (2) is applied to a bridge rectifier (3) to produce a DC source that is routed through protective impedance (4) to the output terminals (15) that connect to a load (11). The protective impedance (4) is sized to provide the test signal appropriate for the intended load (11).

When AC power is first applied, the Controller (8) detects the presence of power through the AC monitor (7). When this occurs the Controller (8) begins to monitor the output voltage through the DC voltage monitor (6). If the voltage detected by the DC voltage monitor (6) exceeds a determined level before a determined time the Controller (8) will close the protective impedance bypass switching element (5), applying full power to the load.

This sequence will apply full power to a properly connected load (11), but will deny power to improperly connected loads (12)-(14). Specifically:

An improper load with forward biased diodes (12) will clamp the output voltage at a low level. As a result, the voltage detected by DC voltage monitor (6) will not rise to the determined level, the controller (8) will leave protective impedance (4) in the circuit, and this will cause the system (1) to deny full-power connection.

A load with a polarized capacitor that has been connected in reverse (13) can also be detected/protected by this system. The reverse capacitor within (13) will not charge fully through the protective impedance (4) because of the capacitor's leakage current. As a result, once again, the voltage detected by the DC voltage monitor (6) will remain below the determined level for the determined period, so that the controller (8) will leave protective impedance (4) in the circuit, and this will cause the system (1) to deny full-power connection.

An improper load with a shorted switch (14) will also clamp the output voltage near zero volts. As a result, once again, the voltage detected by the DC voltage monitor (6) will remain below the determined level for the determined period, so that the controller (8) will leave protective impedance (4) in the circuit, and this will cause the system (1) to deny full-power connection.

The controller (8) may optionally be connected to an annunciator (9) which can be an audible alarm, as shown, or a flashing light or other attention-getting device. The controller (8) would then be programmed to actuate the annunciator (9) to warn when an improper load is detected.

Similarly, the controller (8) may be programmed to assert a “Power OK” signal (10) when a proper load is detected, which can then be used to actuate an indicator, or by other apparatus. For example, as a safety measure or to properly sequence a work flow, equipment downstream of the load can be set to look for “Power OK” (10) before powering up or starting.

When the loss of AC power is detected through the AC monitor (7), the controller (8) may be programmed to open the protective impedance bypass switching element (5).

### EXAMPLE 2

### Isolated AC-DC Converter with Voltage Monitor

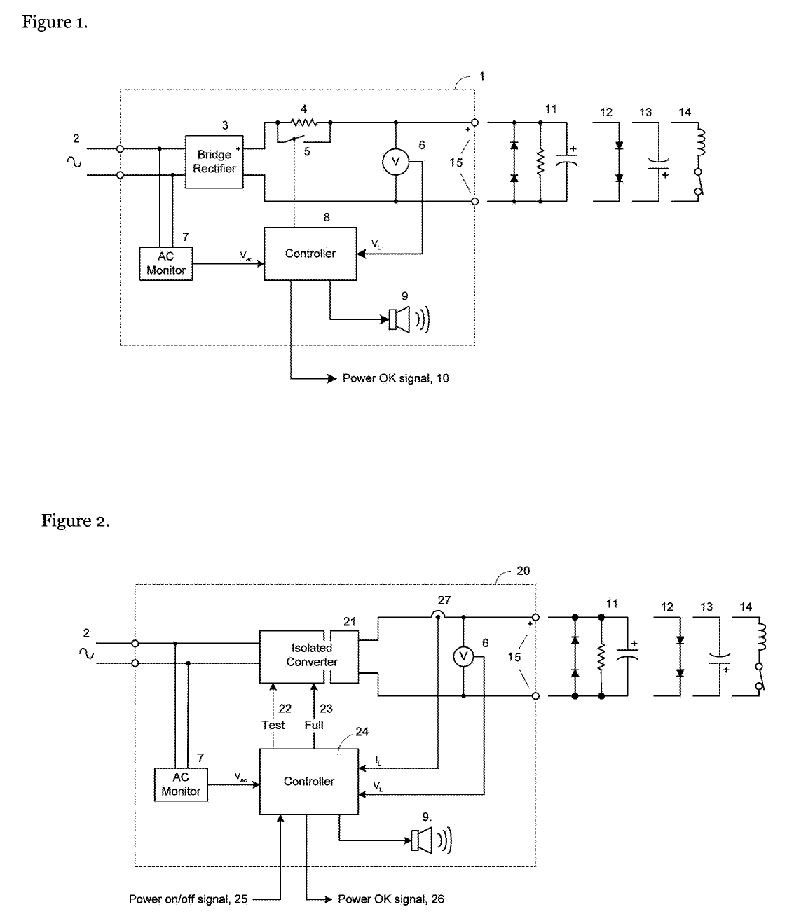

Another embodiment of this invention is an isolated AC-DC Converter illustrated in FIG. 2. Where the elements in this embodiment are the same as in the embodiment of FIG. 1, the elements will not be discussed in detail here. Such elements will have the same reference numbers in FIGS. 1 and 2. As in FIG. 1, reference (11) represents a “proper” load, and references (12),(13) and (14) represent “improper” loads, as will be described in more detail below.

In this embodiment AC power (2) is applied to an Isolated Converter stage (21). The “isolated converter” is a DC-DC converter that uses an energy transfer method/mechanism which is galvanically isolated between its input and output circuits; most often this is accomplished via a magnetic transformer. A fuller name for such a converter would be an “isolated switching converter” which someone skilled in the art would understand. The output of the Isolated Converter (21) is monitored by a voltage sensor (6) and a current sensor (27).

The Isolated Converter (21) provides a DC source that can be operated in two modes: a limited output mode or a full power mode. The limited output mode is sized to provide the test signal appropriate for the intended load (11).

When AC power is first applied, the Controller (24) detects the presence of power through the AC monitor (7). When AC power is applied and the Power on-off signal (25) is in the “on” state, the Controller (24) asserts the Test command (22) and the isolated converter stage (21) then applies the limited output mode test signal to the output power port (15). The controller (24) then begins monitoring the output port (15) through the DC voltage monitor (6) and the current monitor (27).

If the output voltage exceeds a determined level and the output current is below a determined level at the end of a determined test period, the Controller (24) will then assert the Full command (23) applying full power to the load (11).

This sequence will apply full power to a properly connected load (11) but will deny power to improperly connected loads (12)-(14).

An improper load with forward biased diodes (12) will clamp the output voltage at a low level while demanding a high test current. As a result, the voltage detected by DC voltage monitor (6) will not rise to the determined level, the current detected by current detector (27) will exceed the determined amount, or both. The controller (8) will leave the “Test” command asserted, and this will cause the system (1) to deny full-power connection.

A load with a polarized capacitor that has been connected in reverse (13) can also be detected/protected by this system. The reverse capacitor within (13) will not charge fully because of the capacitor's leakage current. As a result, the voltage detected by the DC voltage monitor (6) will remain below the determined level for the determined period, so that the controller (8) will leave the “Test” command asserted, and this will cause the system (1) to deny full-power connection.

An improper load with a shorted switch (14) will clamp the output voltage near zero volts while demanding a high test current. As a result, the voltage detected by DC voltage monitor (6) will not rise to the determined level, the current detected by current detector (27) will exceed the determined amount, or, most likely, both. The controller (8) will leave the “Test” command asserted, and this will cause the system (1) to deny full-power connection.

When the loss of AC power is detected through the AC monitor (7), the controller (24) may be programmed to de-assert both the Test command (22) and Full command (23).

### EXAMPLE 3

### AC-DC Rectifier with Pulsed Output Test Signal

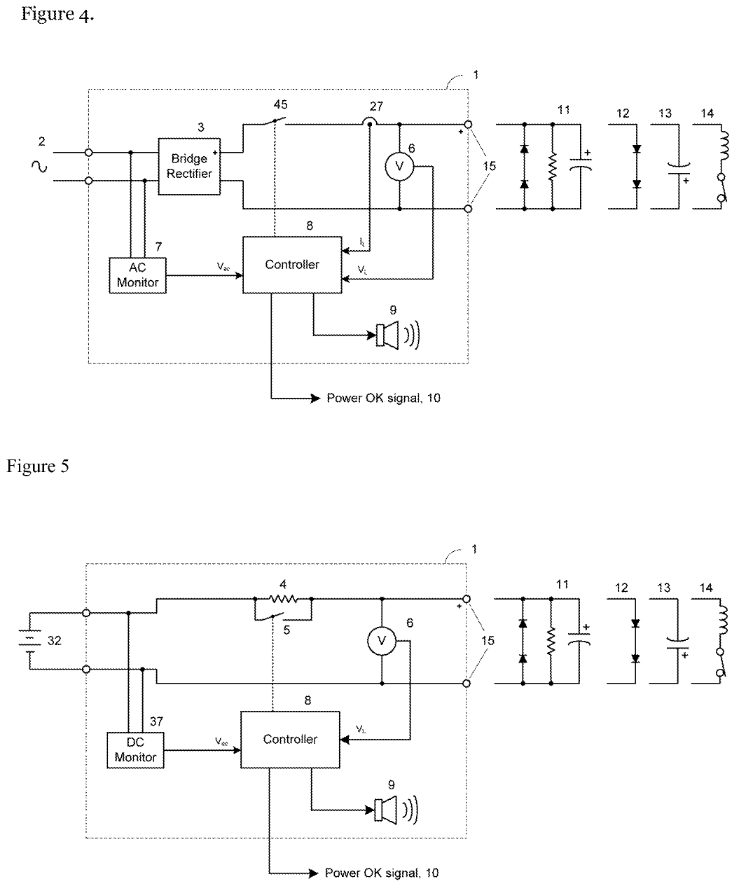

FIG. 4 illustrates an AC-DC rectifier, which includes a specific embodiment of this invention. Where the elements in this embodiment are the same as in the embodiment of FIG. 1, the elements will not be discussed in detail here. Such elements will have the same reference numbers in FIGS. 1 and 4. As in FIG. 1, reference (11) represents a “proper” load, and references (12),(13) and (14) represent “improper” loads, as will be described in more detail below.

In this embodiment AC power (2) is applied to a bridge rectifier (3) to produce a DC source that is routed through a high-speed switch (45) to the output terminals (15) that connect to a load (11).

When AC power is first applied, the Controller (8) detects the presence of power through the AC monitor (7). When this occurs the Controller (8) begins to monitor the output voltage through the DC voltage monitor (6) and output current through current detector (27). The high-speed switch (45) is then closed and opened in sequence for a series of one or more cycles. If the response to the switching sequence as monitored by DC voltage monitor (6) and current detector (27) indicates that the load is properly connected, then the high-speed switch (45) is closed, applying full power to the load.

This sequence will apply full power to a properly connected load (11), but will deny power to improperly connected loads (12)-(14). Specifically:

An improper load with forward biased diodes (12) will clamp the output voltage at a low level while drawing a high amount of current each time the switch (45) is closed. As a result, the voltage detected by DC voltage monitor (6) will not rise to the determined level, the controller (8) will not close switch (45) after the test sequence, and this will cause the system (1) to deny full-power connection.

A load with a polarized capacitor that has been connected in reverse (13) can also be detected/protected by this system. The reverse capacitor within (13) will not charge fully from the series of pulses because of the capacitor's leakage current. As a result, once again, the voltage detected by the DC voltage monitor (6) will remain below the determined level for the determined period, so that the controller (8) will leave protective impedance (4) in the circuit, and this will cause the system (1) to deny full-power connection.

An improper load with a shorted switch (14) will also clamp the output voltage near zero volts for high-speed switch closures of a certain duration. As a result the voltage detected by the DC voltage monitor (6) will remain below the determined level for the determined period, so that the controller (8) will not close switch (45) after the test sequence, and this will cause the system (1) to deny full-power connection.

The controller (8) may optionally be connected to an annunciator (9) which can be an audible alarm, as shown, or a flashing light or other attention-getting device. The controller (8) would then be programmed to actuate the annunciator (9) to warn when an improper load is detected.

Similarly, the controller (8) may be programmed to assert a “Power OK” signal (10) when a proper load is detected, which can then be used to actuate an indicator, or by other apparatus. For example, as a safety measure or to properly sequence a work flow, equipment downstream of the load can be set to look for “Power OK” (10) before powering up or starting.

When the loss of AC power is detected through the AC monitor (7), the controller (8) may be programmed to open the high-speed switch (45).

### EXAMPLE 4

### DC-DC Implementation

FIG. 5 shows an embodiment of the invention, as it might be used in a pure DC embodiment. Where the elements in this embodiment are the same as in the embodiment of FIG. 1, the elements will not be discussed in detail here. Such elements will have the same reference numbers in FIGS. 1 and 5. As in FIG. 1, reference (11) represents a “proper” load, and references (12), (13) and (14) represent “improper” loads, as will be described in more detail below.

The embodiment of FIG. 5 is essentially the same as that of FIG. 1, except that the AC supply (2) is replaced by a DC supply (32), here shown as a battery, although it could be any sort of external DC supply. Since the power source (32) is already DC, the rectifier (3) of FIG. 1 is not required, and the AC monitor (7) is replaced by a DC monitor (37).

When DC power is first applied, the Controller (8) detects the presence of power through the DC input monitor (37). When this occurs the Controller (8) begins to monitor the output voltage through the DC voltage monitor (6). If the voltage detected by the DC voltage monitor (6) exceeds a determined level before a determined time the Controller (8) will close the protective impedance bypass switching element (5), applying full power to the load.

This sequence will apply full power to a properly connected load (11), but will deny power to improperly connected loads (12)-(14), as explained above in connection with FIG. 1—see the discussion of that figure, above.

When the loss of DC power is detected through the DC monitor (37), the controller (8) may be programmed to open the protective impedance bypass switching element (5).

### Method of the Invention

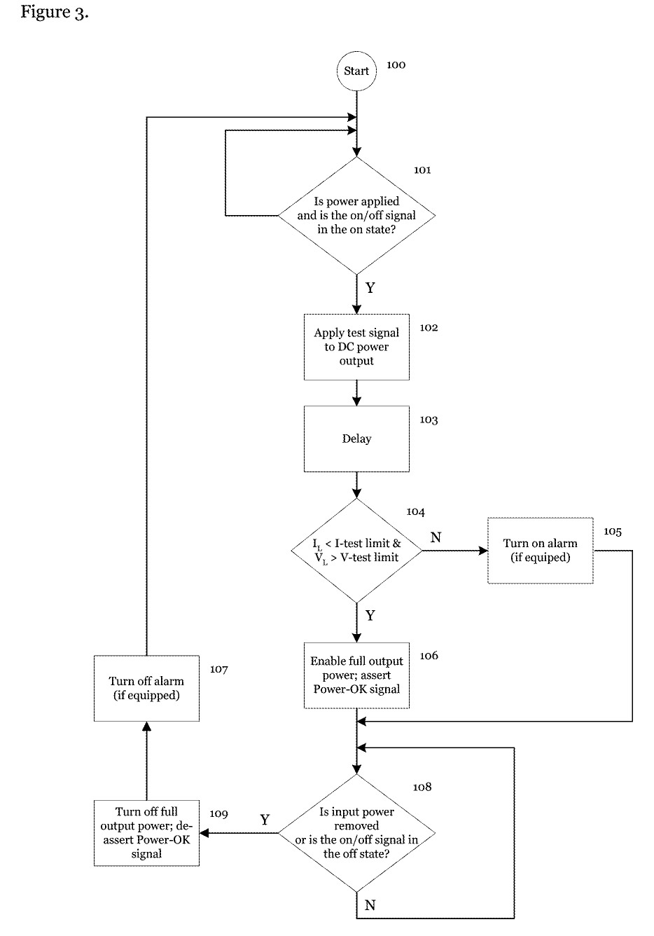

One example method that utilizes the apparatus elements to accomplish the functions outlined above is diagramed in the flowchart FIG. 3.
100. The method starts.
101. The method checks for the application of power to the apparatus (and, if the apparatus is so equipped, for the assertion of a power-on control signal).
102. The DC power output apparatus applies a test signal to access the load(s) which are connected to it. The test signal may be a combination of at least one of the following: limited DC current, limited DC voltage, a series of voltage pulses, a series of current pulses, an AC current, an AC voltage.
103. A delay is provided.
104. The method checks for low voltage and/or high current at the power output, relative to selected test limits.
105. If the check is not OK (i.e. voltage is below the limit and/or current is above the limit, or other checks as appropriate for the test signal chosen) an alarm is sounded (if equipped), and the power-on step 106 is bypassed.
106. If the check is OK (i.e. voltage is above the limit and/or current is below the limit, or other checks as appropriate for the test signal chosen) an alarm is sounded (if equipped), full power is applied to the output port. This may be done by bypassing a protective impedence, or through a controller/converter setting, or other means.
108. The method then loops through a check for an indication that input power has been removed or the on/off signal is in the “off” state. If neither condition is true, the step loops until one or the other (or both) is true. When either (or both) of the conditions are true, then:
109. The method turns off full output power and de-asserts the “power OK” signal. 107. The alarm is turned off, if so equipped (107), and the method loops back to step 101 to test for another cycle.

Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

What is claimed is:

1. A DC power supply for use with DC loads, comprising:
a) a DC power source having a DC output;
b) a power output coupled to the DC output of the DC power source, for connection to a DC load;
c) a voltage sensor measuring DC voltage at the power output, coupled to an;
d) a controller having an input coupled to the voltage sensor, a power on/off signal input, and a control output; and
e) a test signal circuit having an input coupled to the DC output of the DC power source, an output coupled to the power output, and a control input coupled to the control output of the controller, the test signal circuit controlling the energy coupled through the circuit such that the circuit couples either full power or a reduced power from the DC output of the DC power source to the power output in response to a signal on the control input;
the controller being programmed such that when power is to be applied to the load, the controller sends a signal to the test signal circuit to couple a reduced power from the DC output of the DC power source to the power output, and
when the controller determines that the load is acceptable based at least on the voltage from the voltage sensor, the controller sends a signal to the test signal circuit to couple full power from the DC output of the DC power source to the power output.

2. The power supply of claim 1, in which the controller determines the load is acceptable if the voltage at the power output rises above a determined value within a determined period.

3. The power supply of claim 1, further comprising a current sensor between the DC output of the DC power source and the power output, having an output representative of current flowing through the inductor coupled to an input on the controller, in which the controller determines that the load is acceptable based also on the current measured by the current sensor.

4. The power supply of claim 3, in which the controller determines the load is acceptable if the current remains below a determined value after a determined period.

5. The power supply of claim 1, in which the test signal circuit comprises:
a) an impedance between the DC output of the DC power source and the power output; and
b) a bypass switch across the impedence having a control input, such that a signal on the control input closes the switch to bypass the impedance.

6. The power supply of claim 1, in which the test signal circuit comprises a high-speed switch between the DC output of the DC power source and the power output, having a control input; and the controller is programmed put a pulsed signal on the control input to close and open the switch, such that a test signal is created in the form of pulses.

7. The power supply of claim 1, in which the DC power source is an AC-DC converter having a power input for connection to AC power from a power source and a DC output.

8. The power supply of claim 7, in which the AC-DC converter is an isolated converter, and the test signal circuit is integrated into the converter, the control input of the test signal circuit causing the isolated converter to switch between a limited output mode and a full power mode.

9. The power supply of claim 7, further comprising an AC monitor having an input coupled to the AC power input and an output coupled to an input of the controller, such that the controller determines power is to be applied to the load based on the output of the AC monitor indicating that power is present at the AC power input.

10. The power supply of claim 1, further comprising a DC monitor having an input coupled to the DC power source and an output coupled to an input of the controller, such that the controller determines power is to be applied to the load based on the output of the DC monitor indicating that power is present.

11. The power supply of claim 1, further comprising a power on/off signal coupled to an input of the controller, such that the controller determines power is to be applied to the load based on a state of the power on/off signal.

12. The power supply of claim 1, further comprising a power on output on the controller, the controller being programmed such that a signal is asserted on the power on output when the controller determines that the load is acceptable.

13. The power supply of claim 1, further comprising an annunciator coupled to an output of the controller, the controller being programmed such that the annunciator is activated when the controller determines that the load is not acceptable.

14. A method of controlling a DC power supply, comprising:
a) detecting that power is to be applied to a load;
b) applying a reduced energy test signal to the load;
c) detecting if the load is acceptable based on at least a voltage at a load output of the power supply;
d) applying full power to the load if the load is acceptable.

15. The method of claim 14, in which load is determined to be acceptable if the voltage at the load output rises above a determined value within a determined period.

16. The method of claim 14, in which the load is determined to be acceptable if a current measured by a current sensor in series with the load remains below above a determined value after a determined period.

17. The method of claim 14, in which the test signal is applied by passing current to the load through an impedance, and full power is applied by bypassing the impedance.

18. The method of claim 14, in which the test signal is applied in the form of pulses.

19. The method of claim 14, in which the test signal is applied by causing an isolated converter to switch between a limited output mode and a full power mode.

20. The method of claim 14, in which it is determined that power is to be applied to the load by detecting power present at an AC power input.

21. The method of claim 14, in which it is determined that power is to be applied to the load by detecting a state of a power on/off signal.

22. The method of claim 14, further comprising asserting a power on output when the load is acceptable.

23. The method of claim 14, further comprising activating an annunciator when the load is not acceptable.
